(19) United States
(12) Patent Application Publication
(10) Pub. No.: US 2026/0147076 A1
(43) Pub. Date: May 28, 2026

(54) COMPUTER-IMPLEMENTED METHOD FOR DETERMINING A MAGNETIC RESONANCE IMAGE DATA SET, IMAGE PROCESSING FACILITY, COMPUTER PROGRAM, AND ELECTRONICALLY READABLE DATA CARRIER

(71) Applicant: Siemens Healthineers AG, Forchheim (DE)

(72) Inventors: Mario Zeller, Erlangen (DE); Marcel Dominik Nickel, Herzogenaurach (DE); Christian Meixner, Erlangen (DE)

(21) Appl. No.: 19/374,144

(22) Filed: Oct. 30, 2025

(30) Foreign Application Priority Data
Nov. 22, 2024 (DE) 10 2024 211 204.6

(51) Int. Cl. G01R 33/565; G01R 33/56; G06T 11/00

(52) U.S. Cl. CPC G01R 33/56545; G01R 33/5608; G06T 12/30; G06T 2211/441

(57) ABSTRACT

A computer-implemented method is provided for determining a magnetic resonance image data set from a measurement data set of magnetic resonance imaging. The measurement data set is recorded with parallel imaging using a receiving coil arrangement having a plurality of receiving channels in a recording geometry. The determination of the magnetic resonance image data set includes a reconstruction process using at least one trained image processing function, wherein the reconstruction process includes a data consistency act for improving the correspondence of a result image with the measurement data set in dependence upon a regularization value. The intensity of the noise reduction of the reconstruction process is modified in dependence upon location in the data consistency act, wherein the modification is performed in dependence upon a modification variable that locally describes the expected noise reduction intensity of the unmodified reconstruction process on the basis of the recording geometry.

The present patent document claims the benefit of German Patent Application No. 10 2024 211 204.6, filed Nov. 22, 2024, which is hereby incorporated by reference in its entirety.

### TECHNICAL FIELD

The disclosure relates to a computer-implemented method for determining a magnetic resonance image data set from a measurement data set of magnetic resonance imaging, wherein the measurement data set, in particular undersampled, is recorded with parallel imaging using a receiving coil arrangement having a plurality of receiving channels in a recording geometry, and the determination of the magnetic resonance image data set includes a reconstruction process using at least one trained image processing function, wherein the reconstruction process includes a data consistency act for improving the correspondence of a result image with the measurement data set. The disclosure further relates to an image processing facility, a computer program, and a non-transitory electronically readable data carrier.

### BACKGROUND

In imaging, receiving coil arrangements having a plurality of coil elements, to which receiving channels are allocated, are used in order to be able to receive magnetic resonance signals in a temporally parallel manner via the different receiving channels. The known spatial position and sensitivity of the coil elements is used in order to determine the spatial location of the magnetic resonance signal in an improved manner. Parallel imaging may be combined with undersampling, since this additional information renders it possible for the number of phase encoding acts during image acquisition to be reduced. In this way, the recording time may be significantly reduced.

In a reconstruction process, a magnetic resonance image data set of the recording area is reconstructed from the measurement data of the individual receiving channels. Conventional, classic reconstruction approaches use either sensitivity information, in particular sensitivity maps, or reconstruction weights in order to determine the magnetic resonance image data sets. Purely as an example, reference is made to the articles by Klaas P. Pruessmann et al., “SENSE: Sensitivity Encoding for Fast MRI,” Magnetic Resonance in Medicine 42 (1999), pages 952 to 962, and M. A. Griswold et al., “Generalized autocalibrating partially parallel acquisitions (GRAPPA),” Magnetic Resonance in Medicine 47 (2002), pages 1202 to 1210.

In conventional reconstruction processes, for example, in the case of GRAPPA, demanding parameters of the recording protocol, (e.g., extremely high acceleration factors, i.e., intense undersampling), lead to an intense increase in noise in areas that have a high g-factor (geometry factor) due to the geometric arrangement of the receiving coil arrangement. Recently, however, iterative methods have also been proposed which, as part of an optimization, introduce the result of a trained image processing function, a so-called prior image, into the reconstruction result in a regularized manner. An application of such an approach is described, for example, in an article by H. Wie et al., “Enhancing gadoxetic acid-enhanced liver MRI: a synergistic approach with deep learning CAIPIRINHA-VIBE and optimized fat suppression techniques,” European Radiology 34 (2024), pages 6712-6725. The cost function of the optimization may include a data consistency term (mapping of the measurement data) and a second term that is weighted in dependence upon a regularization value, which deviates as little as possible from the prior image. The trained image processing function, for example, including a neural network, has a noise-reducing effect. Therefore, demanding parameters of the recording protocol tend to lead to an increased smoothing in areas of high g-factor. This is counterintuitive for a viewer, since the viewer sees noise as an indicator of less reliable image regions. In addition, there is the risk that image features are smoothed out, and, for example, small lesions or the like are no longer reliably visible.

In order to solve this problem, it has so far been proposed to convey the different behavior of conventional reconstructions and those that use smoothing or noise-reducing trained image processing functions in manuals and through further training.

### Summary and Description

The object of the disclosure is therefore to specify a possibility for obtaining intuitively more comprehensible and/or also smaller image features of recognizable reproducing magnetic resonance image data sets, even when using trained image processing functions in reconstruction processes in parallel imaging.

In order to achieve this object, a computer-implemented method, an image processing facility, a computer program, and a non-transitory electronically readable data carrier are disclosed. The scope of the present disclosure is defined solely by the appended claims and is not affected to any degree by the statements within this summary. The present embodiments may obviate one or more of the drawbacks or limitations in the related art.

In certain methods, the intensity of the noise reduction of the reconstruction process is modified in dependence upon location in the data consistency act, wherein the modification is performed in dependence upon a modification variable which locally describes the expected noise reduction intensity of the unmodified reconstruction process on the basis of the recording geometry.

An approach is therefore proposed for reducing the problem of excessive smoothing in image regions with a high g-factor, in which a location-dependent scaling of the noise reduction intensity is performed for the reconstruction process as a whole. The spatially varying intensity of noise reduction provides that noisy areas in the image result, i.e., the magnetic resonance image data set, are significantly more recognizable. The user receives an image impression that is comparable to the conventional method and is therefore better able to assess whether the selected protocol settings (for example, acceleration factor, image resolution and the like) are suitable or were selected to be too high. In addition, since the noise is removed less aggressively in areas that show a high noise amplification, smaller image features are smoothed less and are obtained in an improved manner in the final image result. For example, experiments with 3×3 accelerated three-dimensional measurement data sets and reconstruction processes with and without location-dependent modification of the noise reduction have shown that, for example, small lesions remain clearly visible despite the higher noise that is obtained in the approach described here, while they are less easily recognizable without location-dependent modification of the noise reduction.

The modification is dependent on the recording geometry, in particular the arrangement of the coil elements of the receiving coil arrangement, which determines in which areas there is particularly intense noise or a low signal-to-noise ratio and thus a noise amplification in many conventional methods (for example, pure SENSE or GRAPPA). Therefore, the modification is performed directly based on background knowledge of the cause of the different noise behavior in the measurement data set. The modification takes place outside the trained image processing function, thus without it having to be changed or adapted. In the data consistency act, the correspondence of the current image with the measurement data is improved in the sense of the signal model, in the case of only one sequence of the application of the trained image processing function and the data consistency act therefore of the magnetic resonance data set as a (single) result image, otherwise the result image of a corresponding iteration act. In the data consistency act, the result of the trained image processing function and the data consistency are combined, wherein the regularization value describes the corresponding weighting. At least one arithmetic image is determined in the reconstruction process by at least one of the at least one trained image processing function, wherein the arithmetic image is introduced into the reconstruction result in the data consistency act, taking into account the regularization value. The regularization value may therefore also be referred to as a weighting value or also as the step size of the data consistency act. The combination of recording geometry and signal model, noise-reducing processing by the trained image processing function and data consistency act results in a noise reduction in the unmodified reconstruction process. In other words, the reconstruction process in which the modification of the noise reduction intensity that is proposed has not yet been used, where a noise amplification occurred in conventional methods. The reason for this, however, may be seen in the parallel imaging and its specific implementation as well as the signal model used, so that the modification variable depicts exactly these aspects.

In summary, by spatially varying modification of the noise reduction intensity, without having to change the trained image processing function, the advantages of a more intuitive image impression, comparable to conventional reconstruction approaches, which increases the safety of radiologists and other users, and the increased conspicuity of small image structures are achieved.

A trained function may map cognitive functions that people associate with other human brains. By training based on training data (machine learning), the trained function is able to adapt to new circumstances and to detect and extrapolate patterns. Another expression for “trained function” is “trained machine learning model.”

Parameters of a trained function may be adjusted by training. In particular, supervised learning, semi-supervised learning, unsupervised learning, reinforcement learning, and/or active learning may be used. In addition, representation learning (also known as “feature learning”) may also be used. The parameters of the trained function may in particular be adapted iteratively by a plurality of training acts. In particular, a certain cost function may be minimized during the training. For example, the backpropagation algorithm may be used in the training of a neural network.

A trained function may include a neural network, a support vector machine (SVM), a decision tree, and/or a Bayesian network. Additionally, or alternatively, the trained function may be based on k-means clustering, Q-learning, genetic algorithms, and/or allocation rules. In particular, a neural network may be a deep neural network, a convolutional neural network (CNN), or a deep CNN. In addition, the neural network may be an adversarial network, a deep adversarial network and/or a generative adversarial network (GAN).

A convolutional neural network (CNN) is a neural network that uses a convolutional operation instead of general matrix multiplication in at least one of its layers, the so-called convolutional layer. In particular, a convolutional layer may perform a scalar product of one or more convolution cores with the incoming data/images of the convolutional layer, wherein the entries of the one or more convolution cores are the parameters or weights that are adjusted by training. In particular, the inner Frobenius product and the ReLu activation function may be used. A CNN may include additional layers, for example pooling layers, fully connected layers and normalization layers.

CNN allows input images to be processed in an extremely efficient manner, since a convolutional operation based on different cores may extract a wide variety of image features, so that the relevant image features may be found during the training by adjusting the weights of the convolution cores. In addition, based on the sharing of the weights in the convolutional layer cores, fewer parameters have to be trained, so that overfitting in the training phase is avoided and faster training or a larger number of layers in the CNN are allowed, so that the performance of the network is increased.

In certain examples, the reconstruction process may use sensitivity information that describes the sensitivity of the receiving coil arrangement (SENSE), or else work with reconstruction weights, for example, GRAPPA weights. The sensitivity information includes in particular sensitivity maps for each receiving channel or each at least one coil element that is allocated to the receiving channel. In both approaches, the reconstruction process corresponds to the combination of the information of the individual receiving channels into an overall image, wherein, in addition, the undersampling, if present, is compensated. The reconstruction result of the reconstruction process (and thus the last determined result image) is the magnetic resonance image data set.

The approach described here is suitable in particular for iterative approaches in which the trained image processing function is used in particular more frequently. Thus, expedient embodiments provide that in the reconstruction process in a plurality of iteration acts in each case: an arithmetic image, in particular a prior image, is determined for each iteration act after the first iteration act by the trained image processing function from a result image of the preceding iteration act; and a result image of the iteration act is determined from the measurement data set and the arithmetic image of the iteration act, taking into account the regularization value that is allocated to the iteration act, which describes a weighting,

In this case, the arithmetic image may correspond to the output data of the trained processing function, that is to say its result, the previous result image in particular being used as input data. In particular, the arithmetic image may be a so-called prior image (“image prior”). The arithmetic image for the first iteration act may be defined, for example, as a starting image containing zeros and/or a constant image value. Other determination of the arithmetic image, in particular in dependence upon the measurement data set, is also conceivable.

The iteration may be constructed to minimize a cost function that includes a data consistency term that describes the best possible correspondence of the result image with the measurement data set, and a second term that describes the best possible correspondence of the prior image with the measurement data set and that is weighted using the regularization value.

With particular advantage, the regularization values and/or the trained image processing function for the different iteration acts may be at least partially different. The regularization values may be part of the machine learning for the reconstruction process as a whole. It may therefore be provided that the regularization values are also learned during training of the at least one image processing function. In this way, an optimal reconstruction procedure may be determined overall.

It is also conceivable in principle to use only a few iteration acts. For example, after the use of a defined start image, only one further iteration act may take place, which uses the trained image processing function. In certain examples, a plurality of iteration acts may be used. The number of iteration acts may be predefined so that, for example, the reaching of this defined number may be checked as a condition for the end of the iteration in which the last result image is used as a magnetic resonance image data set.

In certain examples, a reconstruction process may be used in the following, in which an iterative regularized SENSE reconstruction is used, in which the arithmetic image is determined as a prior image for the regularization by at least one trained image processing function that has a U-Net architecture. In other words, data consistency acts are alternately performed in order to relate the measurement data to the result image, and image improvement measures for determining an arithmetic image, for example, a prior image, are performed by the trained image processing function for the next data consistency act. The present disclosure may also be transferred to other specific embodiments apart from this purely illustrative example.

Formulated schematically, the optimization problem of this iterative regularized SENSE reconstruction may be written, for example, as:

$$\hat{m} = {arg min}_{m} ( {‖ Sm - y ‖}^{2} + \frac{1}{{λ}^{2}} {‖ m - z ‖}^{2} ) \qquad ( 1 )$$

In this equation, S denotes the coil sensitivities, e.g., the sensitivity information in the form of the sensitivity matrix, which may be determined from the sensitivity maps; m denotes the result image to be optimized; y denotes the recorded, undersampled measurement data of the measurement data set; λ denotes the regularization value (regularization factor); and z denotes the arithmetic image or prior image. The first term is therefore the data consistency term, the second term is a regularization term, which ultimately also describes the noise propagation in the sense of the signal model. This approach may also be referred to as “Tikhonov regularization.”

For regular undersampling with acceleration factor R, the optimization may be performed in a plurality of blocks, which each contain R aliased voxels. If the measurement data y is transformed into the image space, where it corresponds to zero-filled coil images of the respective receiving channels that are affected by aliasing, each decoupled block may be solved by a singular value decomposition in matrices U Σ V⁺ and it is obtained as an analytical data consistency act for each iteration act n:

$${\hat{m}}_{n + 1} = V \frac{1}{1 + {λ}_{n}^{2} {\sum }^{2}} {V}^{+} ( {λ}_{n}^{2} {S}^{+} y + {z}_{n} ) \qquad ( 2 )$$

In this case, for the first iteration, Z₀ may equal 0. For each further iteration act, n>0 is zₙ=ƒₙ(mₙ), wherein ƒₙ describes the application of the at least one trained image processing function. In certain examples, different trained image processing functions may be applied for each iteration act. The parameters of the trained image processing function(s) and the regularization values λₙ are then determined together by machine learning in a training process, so that a clearly defined sequence is created.

The regularization value λ may be understood as a weighting value or step size of the data consistency act. In particular, \hat{m}=z is for λ→0, while one obtains the unregularized SENSE minimum for λ→∞.

Other specific formulations are also conceivable, for which the statements made here apply and may be used accordingly. For example, a gradient descent method may be used, wherein, starting from the current arithmetic image z of the respective trained image processing function, in the negative direction of the gradient of the SENSE data term,

$$\hat{m} = z - λ {S}^{H} ( Sz - y ) \qquad ( 2 a )$$

Since both the arithmetic image z and the S^{H}(Sz−y) may lie in the image space, the location-dependent regularization or general modification of the noise reduction intensity may be used accordingly, as in the case of equation (2).

In certain examples, the modification may be used by a location-dependent scaling of the regularization value in dependence upon the modification variable, or by a location-dependent scaling of sensitivity information that describes the sensitivity of the receiving coil arrangement, which is used in the reconstruction process, and of the arithmetic image in dependence upon the modification variable, in the case of a non-scaled regularization value.

Both approaches may be easy to implement if the modification variable is spatially resolved. This means that the above-mentioned, highly relevant advantages may be obtained by a small intervention in the algorithm lying outside the trained image processing function, namely the introduction of a location-dependent scaling factor.

The two approaches, which ultimately have an equivalent effect, but in the second case lead to a scaling of the result image, which may easily be removed again, is explained in more detail with regard to the specific, illustrative example briefly explained above.

For a given set of regularization values λₙ, the noise reduction intensity of the reconstruction process is modified by a location-dependent scaling, for example, as:

$${λ}_{n} \to {λ}_{n} / α ( x ) \qquad ( 3 )$$

wherein values 0<α<1 lead to a greater emphasis on the data consistency, so that less noise reduction occurs, and wherein α>1 leads to less importance of the data consistency and therefore more noise reduction.

This therefore renders it possible for the noise reduction intensity to be adjusted to a locally acceptable level. This approach is not limited to regular undersampling, but may also be used, in particular outside of the specific, illustrative example, for incoherent or non-Cartesian sampling patterns of the k space. In such a case, the noise reduction intensity and thus the scaling factor may vary, for example, in dependence upon a bias field that is used for image normalization, as a modification variable.

With regard to the second variant explained above, it is expedient for the specific example to consider the optimization problem (1) more explicitly as:

$$\hat{m} ( X ) = {arg min}_{m ( x )} ( {\sum }_{k} {\vert {\sum }_{x} {u}_{kx} {C}_{I , x} {m}_{x} - {y}_{k} \vert}^{2} + {\sum }_{x} \frac{1}{{λ}_{n}^{2} {α}_{x}^{2}} {\vert {m}_{x} - {z}_{x} \vert}^{2} ) \qquad ( 4 )$$

wherein uₖₓ are Fourier coefficients and C describes the sensitivity formation.

If one now rescales:

$${m}_{x} \to {α}_{x} {\tilde{m}}_{x} , {z}_{x} \to {α}_{x} {\tilde{z}}_{x} , {C}_{I , x} \to \frac{{C}_{I , x}}{{α}_{x}} \qquad ( 5 )$$

you get the alternative optimization problem:

$$\hat{m} ( x ) = \frac{1}{{α}_{x}} {arg min}_{\tilde{m} ( x )} ( {\sum }_{k} {\vert {\sum }_{x} {u}_{kx} {\tilde{C}}_{I , x} {\tilde{m}}_{x} - {y}_{k} \vert}^{2} + \frac{1}{{λ}_{n}^{2}} {\sum }_{x} {\vert {\tilde{m}}_{x} - {\tilde{z}}_{x} \vert}^{2} ) \qquad ( 6 )$$

This means that the locally weighted localization of the first variant may also be mapped to an optimization problem with (per iteration act) constant regularization and scaled coil sensitivities as well as scaled prior image, wherein the result of the optimization is also rescaled.

For the case of regular undersampling, a g-factor of a g-factor map that is allocated to the measurement data set may advantageously be used at least in part as the modification variable in such a manner that a lower g-factor leads to a greater noise reduction. It may be utilized here that possibilities for determining the g-factor with regular undersampling are known not only for SENSE approaches (compare the already cited article by Pruessmann et al.), but also for techniques working with reconstruction weights such as GRAPPA, for which, for example, reference is made to the article by Felix A. Breuer et al., “General Formulation for Quantitative g-factor Calculation in GRAPPA Reconstruction,” Magnetic Resonance in Medicine 62 (2009), pages 739 to 746. In the case of regular sampling, g-factor maps are therefore known or determinable. In this embodiment, these also form voxel-by-voxel scaling maps or serve to derive them.

Specifically, it may be provided that a location-dependent scaling factor is used in a scaling, wherein the scaling factor is proportional or inversely proportional to a power of the g-factor at the corresponding position, in particular the corresponding pixel, and/or in order to determine the location-dependent scaling factor, the g-factor is limited or rescaled to a predetermined interval in accordance with the g-factor map. For example, the scaling factor α may be selected as α(x)∝1/g^{p}(x). The power p may be selected heuristically in order to compensate for the dependence on the local conditioning of the data consistency term. In order to avoid an excessive influence, a restriction to a certain value interval for the g-factor may also be made, for example to a value interval of 1 to 5.

If at least in regions g-factor maps are not present, it may be provided that a sensitivity value of a sensitivity map, in particular the sensitivity information, is used at least in part as the modification variable in such a manner that a lower sensitivity leads to a reduced noise reduction. Alternatively, pixel-by-pixel scaling maps may also be derived from predetermined sensitivity maps for the receiving coil arrangement, if necessary already during the design. In this case, the sensitivity is an inverse measure to the g-factor, which means that a higher signal-to-noise ratio is expected at a higher sensitivity, which means that there is less noise and a lower noise reduction effect of the trained image processing function. In an advantageous development in this context, at least a degree of undersampling and/or a sampling scheme may additionally be taken into account in the modification in order to introduce the specific circumstances of the sampling process. Specifically, the degree of undersampling and/or the sampling scheme may be taken into account by transforming the sensitivity map into the k-space, applying the degree of undersampling and/or the sampling scheme and back-transforming into the image space.

Finally, it is also conceivable if or where neither sensitivity maps nor g-factor maps are present that at least one theoretically assumed spatial profile of the sensitivity, in particular a sensitivity model, is used for the modification. Specifically, a two-dimensional Gaussian function may be used as a sensitivity model. Because the coil elements of the receiving coil arrangement may be arranged around the body of a patient to be received, the sensitivity may be higher on the outside than in the interior of the body, away from the coil elements, which may suitably describe a Gaussian function. A scaling map may expediently in turn be derived from the sensitivity model.

For non-regular undersampling, as explained above, a bias field that is used for image normalization may be used as a modification variable.

In addition to the method, the disclosure also relates to an image processing facility for determining a magnetic resonance image data set from a measurement data set of magnetic resonance imaging. In the image processing facility, the measurement data set, in particular undersampled, is recorded with parallel imaging using a receiving coil arrangement having a plurality of receiving channels in a recording geometry. Additionally, a reconstruction unit of the image processing facility is used for determining the magnetic resonance image data set in a reconstruction process using at least one trained image processing function, wherein the reconstruction process includes a data consistency act for improving the correspondence of a result image with the measurement data set in dependence upon a regularization value. Furthermore, the image processing facility has a modification unit for the modification of the intensity of the noise reduction of the reconstruction process in dependence upon location in the data consistency act, wherein the modification is performed in dependence upon a modification variable which locally describes the expected noise reduction intensity of the unmodified reconstruction process on the basis of the recording geometry. All the embodiments in relation to the method may be transferred in a similar manner to the image processing facility with which it is also possible to obtain the already mentioned advantages.

In particular, the image processing facility has at least one processor and at least one storage device. Functional units are formed by hardware and/or software in order to perform acts of the method as described herein. In addition to the already mentioned functional units, (i.e., modification unit and reconstruction unit), further functional units are of course also conceivable in order to realize embodiments of the method and/or to provide further functionalities. The image processing facility may have a first interface in order to receive the measurement data set and possibly further information, for example including sensitivity information, g-factor maps and the like. The reconstruction result, i.e., the magnetic resonance image data set, may be output via a second interface.

The image processing facility may be integrated into a control facility of a magnetic resonance facility. This means that a magnetic resonance facility may include a control facility that is designed to implement the method, in particular by integrating the image processing facility. The functionality of the reconstruction and determination of the magnetic resonance image data set is then integrated directly into the magnetic resonance facility and is available there, for example in order to enable a first viewing of the magnetic resonance image data set.

A computer program may be loaded directly into a storage device or component of an image processing facility and has program code in such a manner that when the computer program is executed on the image processing facility, this image processing facility is caused to perform the acts of a method as described herein. The computer program may be stored in a non-transitory electronically readable data carrier, which therefore includes control information that is stored thereon and the control information includes at least one computer program and is designed in the case of using the data carrier in an image processing facility so as to implement the method.

In order to purely optimize the image impression for an observer, subsequent modifications of the magnetic resonance image data set are also conceivable, which may be carried out as an alternative or in addition to the approach. In particular, such an approach may be used if the reconstruction process does not enable the spatial variation of the noise reduction intensity or does not enable it directly.

In particular, a method for determining a display image to be output from a measurement data set of magnetic resonance imaging is conceivable, wherein the measurement data set, in particular undersampled, is recorded with parallel imaging, in which a receiving coil arrangement having a plurality of receiving channels in a recording geometry is used, and a magnetic resonance image data set is determined in a reconstruction process having a trained image processing function which has a noise-reducing effect. In order to determine the display image from the magnetic resonance image data set that is obtained as a reconstruction result, a randomized or pseudorandomized noise image of the resolution of the magnetic resonance image data set is generated, the noise image is scaled in a location-dependent manner on the basis of at least one modification variable, in particular using a g-factor map, and the noise image is added to the magnetic resonance image data set in order to obtain the display image.

It is therefore conceivable to first determine a “noise map,” i.e., the noise image, in a randomized or pseudo-randomized manner. This noise image may then be scaled for each pixel in accordance with a modification variable, in particular in accordance with the local g factor, and may be added to the reconstruction result in a final act. Alternatively, the scaled noise image may also already be added to an intermediate result during the reconstruction in order to obtain the display image directly as the reconstruction result.

### BRIEF DESCRIPTION OF THE DRAWINGS

Further advantages and details of the present disclosure are evident in the following described embodiments and also with the aid of the drawings.

FIG. 1 depicts a flowchart of an embodiment of the method.

FIG. 2 depicts an example of the functional structure of an image processing facility.

FIG. 3 depicts an example of a magnetic resonance facility.

### DETAILED DESCRIPTION

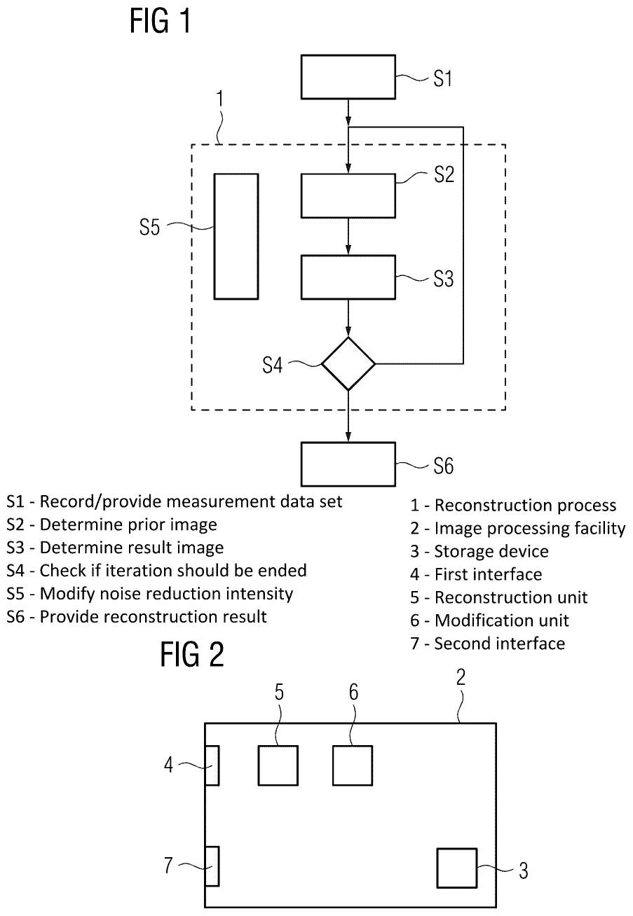

FIG. 1 illustrates a flowchart of an embodiment of the method. In this case, an approach with partial reference to the above-mentioned specific example of the iterative regularized SENSE reconstruction with Tikhonov regularization is explained, without excluding the applicability of the approach to other, in particular iterative, specific approaches, as are known in the prior art.

In act S1, a measurement data set is recorded or provided if the recording has already been completed. The measurement data set is a measurement data set of parallel imaging, for which a receiving coil arrangement having a plurality of receiving channels in a recording geometry is used. The measurement data set is regularly undersampled. Purely by way of example, a SPACE sequence may be used to record the measurement data set. In a three-dimensional measurement data set with three-dimensional recording, for example, a 3×3 undersampling may be present, thus an acceleration factor R=9. In this case, the measurement data (y in the formulas shown above, which are also valid here) is still present, in particular, separately for receiving channels. In a reconstruction process 1 that is now beginning, a magnetic resonance image data set that summarizes the measurement results of the different receiving channels is to be reconstructed from the measurement data.

The reconstruction process 1 includes iteration acts, which in each case include the acts S2 to S4. In this case, a prior image (z) for the respective iteration act (n) is first determined in act S2 as an arithmetic image. In the first iteration act, the prior image is determined in the present case by way of example as a zero image, the image values of which are all equal to zero, or a trained image processing function is applied to such a zero image. In further iteration acts, the prior image is determined by applying a trained image processing function, which is specific to the iteration act and has a noise-reducing effect, to the result image of the preceding iteration act. This means that the result image of the preceding iteration act forms the input data for the trained image processing function, and the prior image of the respective iteration act forms the output data.

In act S3, the data consistency act, the result image of the current iteration act is determined from the prior image and the measurement data, for example, in accordance with the formula (2) presented above. In this case, a regularization is performed by a constant and specific regularization value λₙ for each iteration act, which leads to the prior image being received in a weighted manner. The regularization values λₙ were learned together with the parameters of the trained image processing functions. In act S4, it is then checked whether the iteration is to be ended, namely whether a predetermined number of iteration acts is reached.

In the present case, the noise reduction intensity of the reconstruction process 1 is now modified in a location-dependent manner, which is schematically indicated by act S5. This is done outside the trained image processing function, in the present case by providing a scaling, which is dependent on a modification variable, in the data consistency act. In the specific embodiment discussed in the present case, the regularization values λₙ are scaled in a location-dependent manner, compare the above formula (3). However, it is also conceivable to scale the prior image and the sensitivity, compare the above formula (5).

In the present case, the scaling is performed using a g-factor map provided with the measurement data set, which therefore serves as the basis of a scaling map for the location-dependent scaling. For example, it may be specifically provided that α(x)∝1/g^{p} (x) is selected, wherein the power p is determined heuristically, for example in the range 0.5 to 4. The values of the g-factor may be limited to an interval, for example from 1 to 5.

As an alternative to the g-factor as a modification variable, scaling maps may also be determined from sensitivity values, specifically, for example, sensitivity maps and/or sensitivity models. Scaling maps may therefore describe where a situation in which an excessive noise reduction or smoothing may occur due to the effect of the trained image processing function in the reconstruction process 1 is to be expected due to the recording geometry of the receiving coil arrangement. The location-dependent modification of the noise reduction intensity at least partially compensates for this.

After completion of the reconstruction process 1, the reconstruction result is the last determined result image, which is provided as the magnetic resonance image data set in act S6. For example, it may subsequently be displayed to a user, for example a radiologist or other assessor, who may better assess the corresponding display image due to the intuitively expected noise behavior and may also better recognize smaller image features in areas of poor signal-to-noise ratio.

FIG. 2 illustrates a functional schematic sketch of an image processing facility 2. This first has a storage device 3, in which a wide variety of information, in particular also measurement data sets, result images, prior images, g-factor maps, and the like may be stored. In accordance with act S1, a measurement data set, in particular together with further information such as a g-factor map, may be received via a first interface 4.

The measurement data set is then forwarded to a reconstruction unit 5 for reconstruction, which is designed to perform the reconstruction process 1 in accordance with acts S2, S3, and S4. By the modification unit 6, the location-dependent modification of the noise reduction intensity in accordance with act S5 may be performed, for example by providing the suitable scaling map. The reconstruction result, i.e., the magnetic resonance image data set, is output via a second interface 7 in accordance with act S6.

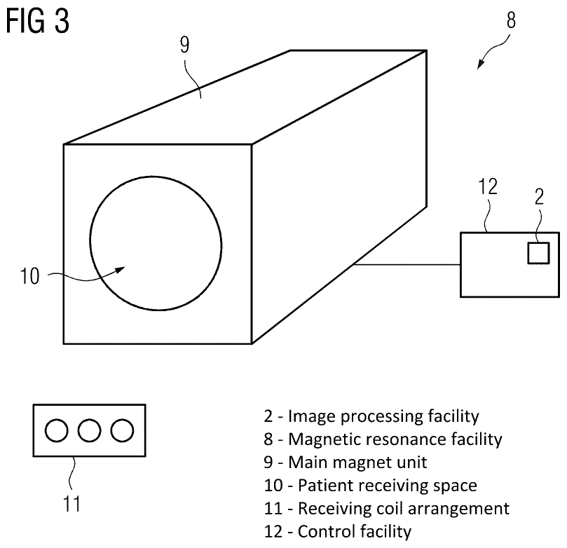

FIG. 3 illustrates a schematic sketch of a magnetic resonance facility 8, which, as is known in principle, has a main magnet unit 9 with a patient receiving space 10, against which a patient may be retracted by a patient couch (not shown in detail here) for recording measurement data sets. In addition to a superconducting main magnet, a gradient coil arrangement and a high-frequency coil arrangement may also be provided in the main magnet unit 9, surrounding the patient receiving space 10. In the present case, a receiving coil arrangement 11 that may be used for parallel imaging is shown schematically.

The operation of the magnetic resonance facility 8 is controlled by a control facility 12, which in the present case also includes the image processing facility 2. In this manner, magnetic resonance image data sets suitable for recorded measurement data sets may be determined directly on site and may also be displayed, in particular on a display facility of the magnetic resonance facility 8.

It is to be understood that the elements and features recited in the appended claims may be combined in different ways to produce new claims that likewise fall within the scope of the present disclosure. Thus, whereas the dependent claims appended below depend on only a single independent or dependent claim, it is to be understood that these dependent claims may, alternatively, be made to depend in the alternative from any preceding or following claim, whether independent or dependent, and that such new combinations are to be understood as forming a part of the present specification.

While the present disclosure has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A computer-implemented method for determining a magnetic resonance image data set from a measurement data set of magnetic resonance imaging, the method comprising:
recording the measurement data set with parallel imaging using a receiving coil arrangement having a plurality of receiving channels in a recording geometry; and
determining the magnetic resonance image data set comprising a reconstruction process using at least one trained image processing function, wherein the reconstruction process comprises a data consistency act for improving a correspondence of a result image with the measurement data set in dependence upon a regularization value,
wherein an intensity of a noise reduction of the reconstruction process is modified in dependence upon location in the data consistency act, and
wherein the modification is performed in dependence upon a modification variable that locally describes an expected noise reduction intensity of an unmodified reconstruction process based on the recording geometry.

2. The method of claim 1, wherein at least one arithmetic image is determined in the reconstruction process by at least one of the at least one trained image processing function, and
wherein the arithmetic image is introduced into the reconstruction result in the data consistency act, taking into account the regularization value.

3. The method of claim 2, wherein, in the reconstruction process, in a plurality of iteration acts in each case:
the arithmetic image is determined for each iteration act after a first iteration act by at least one of the at least one trained image processing function from a result image of a preceding iteration act; and
a result image of the iteration act is determined from the measurement data set and the arithmetic image of the iteration act, taking into account the regularization value that is allocated to the iteration act, which describes a weighting.

4. The method of claim 1, wherein the modification is used by a location-dependent scaling of the regularization value in dependence upon the modification variable, or
wherein the modification is used by a location-dependent scaling of sensitivity information that describes the sensitivity of the receiving coil arrangement, which is used in the reconstruction process, and of an arithmetic image that is determined by at least one of the at least one image processing function, in dependence upon the modification variable, without scaling of the regularization value.

5. The method of claim 4, wherein the arithmetic image is a prior image.

6. The method of claim 1, wherein a g-factor of a g-factor map that is allocated to the measurement data set is used at least in part as the modification variable in such a manner that a lower g-factor leads to a greater noise reduction.

7. The method of claim 6, wherein a location-dependent scaling factor is used in a scaling and the scaling factor is proportional or inversely proportional to a power of the g-factor at a corresponding position, and/or
wherein, in order to determine the location-dependent scaling factor, the g-factor is limited or rescaled to a predetermined interval in accordance with the g-factor map.

8. The method of claim 7, wherein the corresponding position is a corresponding pixel.

9. The method of claim 1, wherein a sensitivity value of a sensitivity map is used at least in part as the modification variable in such a manner that a lower sensitivity leads to a reduced noise reduction.

10. The method of claim 9, wherein at least a degree of undersampling and/or a sampling scheme are additionally taken into account in the modification.

11. The method of claim 1, wherein the measurement data set is an undersampled measurement data set.

12. An image processing facility for determining a magnetic resonance image data set from a measurement data set of magnetic resonance imaging, the image processing facility comprising:
a receiving coil arrangement having a plurality of receiving channels in a recording geometry, wherein the receiving coil arrangement is configured to record the measurement data set with parallel imaging;
a reconstruction unit configured to determine the magnetic resonance image data set in a reconstruction process using at least one trained image processing function, wherein the reconstruction process comprises a data consistency act for improving a correspondence of a result image with the measurement data set in dependence upon a regularization value; and
a modification unit for a location-dependent modification of an intensity of a noise reduction of the reconstruction process in the data consistency act, wherein the location-dependent modification is configured to be performed in dependence upon a modification variable that locally describes an expected noise reduction intensity of an unmodified reconstruction process based on the recording geometry.

13. The image processing facility of claim 12, wherein the measurement data set is an undersampled measurement data set.

14. A non-transitory electronically readable data carrier comprising a computer program that, when executed on an image processing facility, causes this image processing facility to:
record a measurement data set with parallel imaging using a receiving coil arrangement having a plurality of receiving channels in a recording geometry; and
determine a magnetic resonance image data set comprising a reconstruction process using at least one trained image processing function, wherein the reconstruction process comprises a data consistency act for improving a correspondence of a result image with the measurement data set in dependence upon a regularization value,
wherein an intensity of a noise reduction of the reconstruction process is modified in dependence upon location in the data consistency act, and
wherein the modification is performed in dependence upon a modification variable that locally describes an expected noise reduction intensity of an unmodified reconstruction process based on the recording geometry.
